(19) United States
(12) Patent Application Publication
(10) Pub. No.: US 2010/0251069 A1
(43) Pub. Date: Sep. 30, 2010

(54) METHOD AND APPARATUS FOR EFFICIENT MEMORY ALLOCATION FOR TURBO DECODER INPUT WITH LONG TURBO CODEWORD

(75) Inventors: Thomas Sun, San Diego, CA (US); Jing Jiang, San Diego, CA (US); Xinmiao Zhang, San Diego, CA (US); Fuyun Ling, San Diego, CA (US)

Correspondence Address: QUALCOMM INCORPORATED, 5775 MOREHOUSE DR., SAN DIEGO, CA, 92121, US

(73) Assignee: QUALCOMM Incorporated, San Diego, CA (US)

(21) Appl. No.: 12/750,305

(22) Filed: Mar. 30, 2010

Related U.S. Application Data
(60) Provisional application No. 61/165,348, filed on Mar. 31, 2009.

(51) Int. Cl. H03M 13/05; G06F 11/10

(52) U.S. Cl. 714/758; 714/763; 714/784; 714/E11.032; 714/E11.034

(57) ABSTRACT

A method and apparatus for memory allocation for turbo decoder input with a long turbo codeword, the method comprising computing a bit level log likelihood ratio (LLR) of a demodulated signal over a superframe to generate at least one systematic bit LLR and at least one parity bit LLR; storing the at least one systematic bit LLR and the at least one parity bit LLR over the superframe in a decoder memory; and reading the systematic bit LLR and the parity bit LLR over the superframe to decode at least one codeword from the decoder memory.

### CLAIM OF PRIORITY UNDER 35 U.S.C. §119

The present application for patent claims priority to Provisional Application No. 61/165,348 entitled Method and Apparatus for Efficient Memory Allocation for Turbo Decoder Input With Long Turbo Codeword filed Mar. 31, 2009, and assigned to the assignee hereof and hereby expressly incorporated by reference herein.

### BACKGROUND

Wireless communications systems are susceptible to errors introduced in the communications link between the transmitter and receiver. Various error mitigation schemes including, for example, error detection, error correction, interleaving, etc. may be applied to improve the error rate in the communications link. Error detection techniques employ parity bits to detect errors at the receiver. If an error is detected, then the transmitter may be notified to resend the bits that were received in error. In contrast, error correction techniques employ redundant bits to both detect and correct bits that were received in error. For error correction techniques, information bits are transformed into encoded codewords for error protection. In the receiver, the encoded codewords are transformed back into information bits by using the redundant bits to correct errors. Interleaving is another error control technique which shuffles the encoded codewords in a deterministic manner to overcome burst errors introduced in the propagation channel.

### SUMMARY

Disclosed is an apparatus and method for efficient memory allocation for turbo decoder input with a long turbo codeword. According to one aspect, a method for memory allocation for turbo decoder input with a long turbo codeword, the method comprising computing a bit level log likelihood ratio (LLR) of a demodulated signal over a superframe to generate at least one systematic bit LLR and at least one parity bit LLR; storing the at least one systematic bit LLR and the at least one parity bit LLR over the superframe in a decoder memory; and reading the systematic bit LLR and the parity bit LLR over the superframe to decode at least one codeword from the decoder memory.

According to another aspect, an apparatus for memory allocation for turbo decoder input with a long turbo codeword, the apparatus comprising a processor and a memory, the memory containing program code executable by the processor for performing the following: computing a bit level log likelihood ratio (LLR) of a demodulated signal over a superframe to generate at least one systematic bit LLR and at least one parity bit LLR; storing the at least one systematic bit LLR and the at least one parity bit LLR over the superframe in a decoder memory; and reading the systematic bit LLR and the parity bit LLR over the superframe to decode at least one codeword from the decoder memory.

According to another aspect, an apparatus for memory allocation for turbo decoder input with a long turbo codeword, the apparatus comprising means for computing a bit level log likelihood ratio (LLR) of a demodulated signal over a superframe to generate at least one systematic bit LLR and at least one parity bit LLR; means for storing the at least one systematic bit LLR and the at least one parity bit LLR over the superframe in a decoder memory; and means for reading the systematic bit LLR and the parity bit LLR over the superframe to decode at least one codeword from the decoder memory.

According to another aspect, a computer-readable medium storing a computer program, wherein execution of the computer program is for computing a bit level log likelihood ratio (LLR) of a demodulated signal over a superframe to generate at least one systematic bit LLR and at least one parity bit LLR; storing the at least one systematic bit LLR and the at least one parity bit LLR over the superframe in a decoder memory; and reading the systematic bit LLR and the parity bit LLR over the superframe to decode at least one codeword from the decoder memory.

It is understood that other aspects will become readily apparent to those skilled in the art from the following detailed description, wherein it is shown and described various aspects by way of illustration. The drawings and detailed description are to be regarded as illustrative in nature and not as restrictive.

### BRIEF DESCRIPTION OF THE DRAWINGS

FIG. 1 is a block diagram of an illustrative of a two terminal system.

FIG. 2 is a block diagram of an illustrative wireless communications system that supports a plurality of user devices.

FIG. 3 is a block diagram of an illustrative wireless communication system which employs a concatenated code.

FIG. 4 block diagram of an illustrative FLO system with central entity and a plurality of mobile terminals.

FIG. 5 is a diagram of an illustrative turbo packet structure.

FIG. 6 is a diagram of an illustrative 4K code block length turbo packet structure.

FIG. 7 is a diagram of an illustrative input symbol storage arrangement for a code rate of ⅓ and a bit width of 4 bits.

FIG. 8 is a diagram of an illustrative input symbol storage arrangement for a code rate of ½ and a bit width of 6 bits.

FIG. 9 is a diagram of an illustrative input symbol storage arrangement for a code rate of ⅔ and a bit width of 6 bits.

FIG. 10 is a flow diagram for efficient memory allocation for turbo decoder input with a long turbo codeword.

FIG. 11 is a block diagram of an illustrative device for executing the processes for efficient memory allocation for turbo decoder input with a long turbo codeword.

FIG. 12 is a block diagram of an illustrative device for efficient memory allocation for turbo decoder input with a long turbo codeword.

### DETAILED DESCRIPTION

The detailed description set forth below in connection with the appended drawings is intended as a description of various aspects of the present disclosure and is not intended to represent the only aspects in which the present disclosure may be practiced. Each aspect described in this disclosure is provided merely as an example or illustration of the present disclosure, and should not necessarily be construed as preferred or advantageous over other aspects. The detailed description includes specific details for the purpose of providing a thorough understanding of the present disclosure. However, it will be apparent to those skilled in the art that the present disclosure may be practiced without these specific details. In some instances, well-known structures and devices are shown in block diagram form in order to avoid obscuring the concepts of the present disclosure. Acronyms and other descriptive terminology may be used merely for convenience and clarity and are not intended to limit the scope of the present disclosure.

While for purposes of simplicity of explanation, the methodologies are shown and described as a series of acts, it is to be understood and appreciated that the methodologies are not limited by the order of acts, as some acts may, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

The methods and apparatus described herein may be used for various wireless communication networks including those that employ broadcast, multicast and unicast paradigms. The methods and apparatus described herein are suitable for use with mobile multimedia distribution systems such as DVB-H and FLO TV which typically employ both a broadcast and a unicast wireless communication network. Such communication networks may be configured using any number of wireless communication technologies including Code Division Multiple Access (CDMA), Time Division Multiple Access (TDMA), Frequency Division Multiple Access (FDMA), Orthogonal FDMA (OFDMA), Single-Carrier FDMA (SC-FDMA), etc. The terms “networks” and “systems” are often used interchangeably. Each of these technologies may be implemented in a variety of manners. For example, a CDMA network may take the form of Universal Terrestrial Radio Access (UTRA), cdma2000, etc. UTRA includes Wideband-CDMA (W-CDMA) and Low Chip Rate (LCR). Cdma2000 covers IS-2000, IS-95 and IS-856 standards. A TDMA network may be implemented as a Global System for Mobile Communications (GSM) system. An OFDMA network may implement a radio technology such as Evolved UTRA (E-UTRA), IEEE 802.11, IEEE 802.16, IEEE 802.20, Flash-OFDM®, etc. UTRA, E-UTRA, and GSM are part of Universal Mobile Telecommunication System (UMTS). Long Term Evolution (LTE) is an upcoming release of UMTS that uses E-UTRA. UTRA, E-UTRA, GSM, UMTS and LTE are described in documents from an organization named “3rd Generation Partnership Project” (3GPP). cdma2000 is described in documents from an organization named “3rd Generation Partnership Project 2” (3GPP2). These various radio technologies and standards are known in the art.

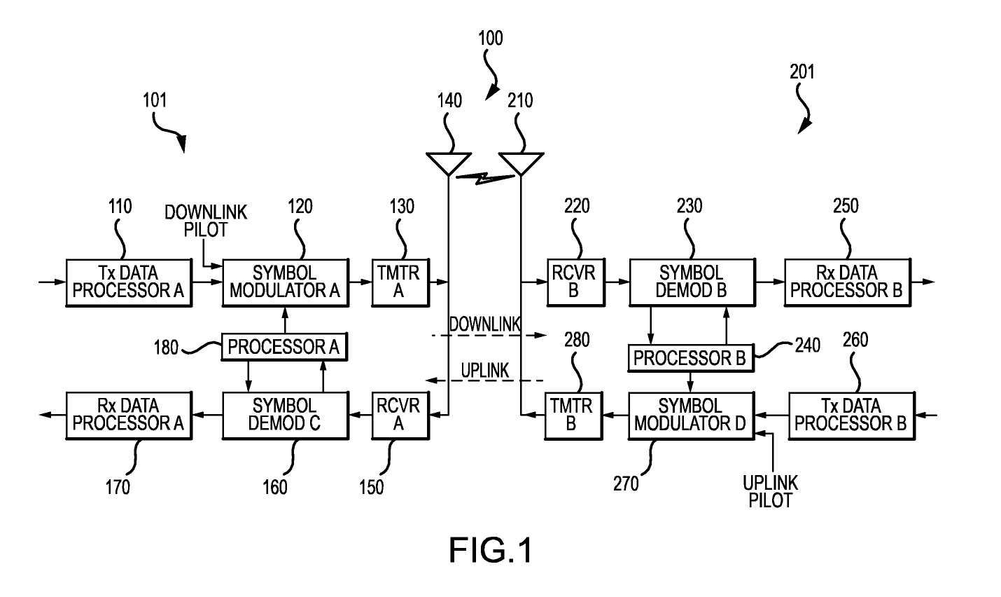

FIG. 1 is a block diagram illustrating an example access node/UE system 100. One skilled in the art would understand that the example access node/UE system 100 illustrated in FIG. 1 may be implemented in an FDMA environment, an OFDMA environment, a CDMA environment, a WCDMA environment, a TDMA environment, a SDMA environment or any other suitable wireless environment.

The access node/UE system 100 includes an access node 101 (e.g., base station) and a user equipment or UE 201 (e.g., wireless communication device). In the downlink leg, the access node 101 (e.g., base station) includes a transmit (TX) data processor A 110 that accepts, formats, codes, interleaves and modulates (or symbol maps) traffic data and provides modulation symbols (e.g., data symbols). The TX data processor A 110 is in communication with a symbol modulator A 120. The symbol modulator A 120 accepts and processes the data symbols and downlink pilot symbols and provides a stream of symbols. In one aspect, it is the symbol modulator A 120 that modulates (or symbol maps) traffic data and provides modulation symbols (e.g., data symbols). In one aspect, symbol modulator A 120 is in communication with processor A 180 which provides configuration information. Symbol modulator A 120 is in communication with a transmitter unit (TMTR) A 130. The symbol modulator A 120 multiplexes the data symbols and downlink pilot symbols and provides them to the transmitter unit A 130.

Each symbol to be transmitted may be a data symbol, a downlink pilot symbol or a signal value of zero. The downlink pilot symbols may be sent continuously in each symbol period. In one aspect, the downlink pilot symbols are frequency division multiplexed (FDM). In another aspect, the downlink pilot symbols are orthogonal frequency division multiplexed (OFDM). In yet another aspect, the downlink pilot symbols are code division multiplexed (CDM). In one aspect, the transmitter unit A 130 receives and converts the stream of symbols into one or more analog signals and further conditions, for example, amplifies, filters and/or frequency upconverts the analog signals, to generate an analog downlink signal suitable for wireless transmission. The analog downlink signal is then transmitted through antenna 140.

In the downlink leg, the UE 201 includes antenna 210 for receiving the analog downlink signal and inputting the analog downlink signal to a receiver unit (RCVR) B 220. In one aspect, the receiver unit B 220 conditions, for example, filters, amplifies, and frequency downconverts the analog downlink signal to a first “conditioned” signal. The first “conditioned” signal is then sampled. The receiver unit B 220 is in communication with a symbol demodulator B 230. The symbol demodulator B 230 demodulates the first “conditioned” and “sampled” signal (e.g., data symbols) outputted from the receiver unit B 220. One skilled in the art would understand that an alternative is to implement the sampling process in the symbol demodulator B 230. The symbol demodulator B 230 is in communication with a processor B 240. Processor B 240 receives downlink pilot symbols from symbol demodulator B 230 and performs channel estimation on the downlink pilot symbols. In one aspect, the channel estimation is the process of characterizing the current propagation environment. The symbol demodulator B 230 receives a frequency response estimate for the downlink leg from processor B 240. The symbol demodulator B 230 performs data demodulation on the data symbols to obtain data symbol estimates on the downlink path. The data symbol estimates on the downlink path are estimates of the data symbols that were transmitted. The symbol demodulator B 230 is also in communication with a RX data processor B 250.

The RX data processor B 250 receives the data symbol estimates on the downlink path from the symbol demodulator B 230 and, for example, demodulates (i.e., symbol demaps), deinterleaves and/or decodes the data symbol estimates on the downlink path to recover the traffic data. In one aspect, the processing by the symbol demodulator B 230 and the RX data processor B 250 is complementary to the processing by the symbol modulator A 120 and TX data processor A 110, respectively.

In the uplink leg, the UE 201 includes a TX data processor B 260. The TX data processor B 260 accepts and processes traffic data to output data symbols. The TX data processor B 260 is in communication with a symbol modulator D 270. The symbol modulator D 270 accepts and multiplexes the data symbols with uplink pilot symbols, performs modulation and provides a stream of symbols. In one aspect, symbol modulator D 270 is in communication with processor B 240 which provides configuration information. The symbol modulator D 270 is in communication with a transmitter unit B 280.

Each symbol to be transmitted may be a data symbol, an uplink pilot symbol or a signal value of zero. The uplink pilot symbols may be sent continuously in each symbol period. In one aspect, the uplink pilot symbols are frequency division multiplexed (FDM). In another aspect, the uplink pilot symbols are orthogonal frequency division multiplexed (OFDM). In yet another aspect, the uplink pilot symbols are code division multiplexed (CDM). In one aspect, the transmitter unit B 280 receives and converts the stream of symbols into one or more analog signals and further conditions, for example, amplifies, filters and/or frequency upconverts the analog signals, to generate an analog uplink signal suitable for wireless transmission. The analog uplink signal is then transmitted through antenna 210.

The analog uplink signal from UE 201 is received by antenna 140 and processed by a receiver unit A 150 to obtain samples. In one aspect, the receiver unit A 150 conditions, for example, filters, amplifies and frequency downconverts the analog uplink signal to a second “conditioned” signal. The second “conditioned” signal is then sampled. The receiver unit A 150 is in communication with a symbol demodulator C 160. One skilled in the art would understand that an alternative is to implement the sampling process in the symbol demodulator C 160. The symbol demodulator C 160 performs data demodulation on the data symbols to obtain data symbol estimates on the uplink path and then provides the uplink pilot symbols and the data symbol estimates on the uplink path to the RX data processor A 170. The data symbol estimates on the uplink path are estimates of the data symbols that were transmitted. The RX data processor A 170 processes the data symbol estimates on the uplink path to recover the traffic data transmitted by the wireless communication device 201. The symbol demodulator C 160 is also in communication with processor A 180. Processor A 180 performs channel estimation for each active terminal transmitting on the uplink leg. In one aspect, multiple terminals may transmit pilot symbols concurrently on the uplink leg on their respective assigned sets of pilot subbands where the pilot subband sets may be interlaced.

Processor A 180 and processor B 240 direct (i.e., control, coordinate or manage, etc.) operation at the access node 101 (e.g., base station) and at the UE 201, respectively. In one aspect, either or both processor A 180 and processor B 240 are associated with one or more memory units (not shown) for storing of program codes and/or data. In one aspect, either or both processor A 180 or processor B 240 or both perform computations to derive frequency and impulse response estimates for the uplink leg and downlink leg, respectively.

In one aspect, the access node/UE system 100 is a multiple-access system. For a multiple-access system (e.g., frequency division multiple access (FDMA), orthogonal frequency division multiple access (OFDMA), code division multiple access (CDMA), time division multiple access (TDMA), space division multiple access (SDMA), etc.), multiple terminals transmit concurrently on the uplink leg, allowing access to a plurality of UEs. In one aspect, for the multiple-access system, the pilot subbands may be shared among different terminals. Channel estimation techniques are used in cases where the pilot subbands for each terminal span the entire operating band (possibly except for the band edges). Such a pilot subband structure is desirable to obtain frequency diversity for each terminal.

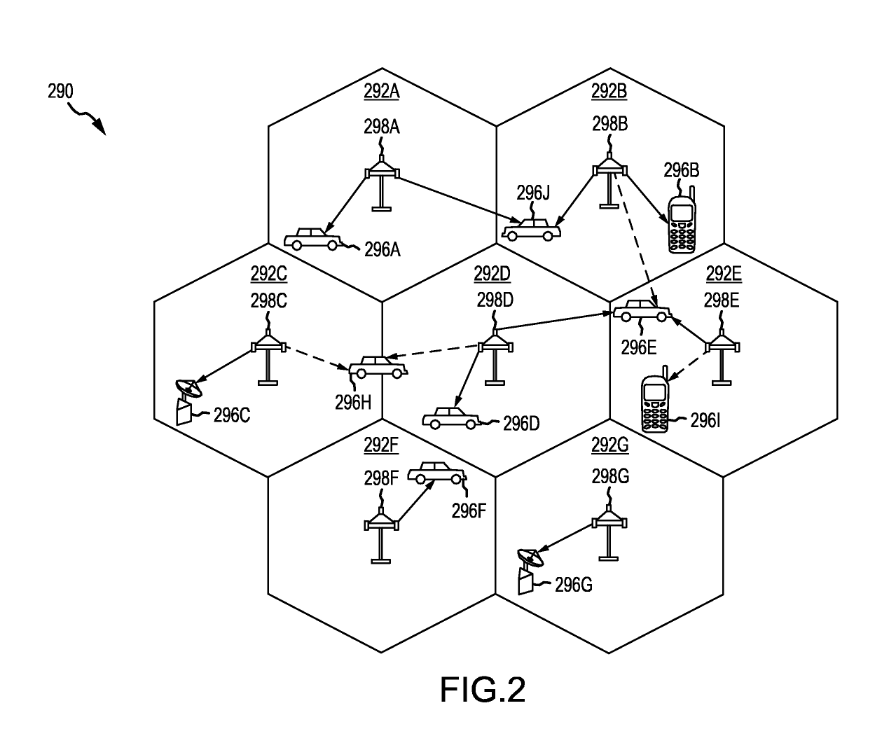

FIG. 2 is a block diagram conceptually illustrating an example of a wireless communications system 290 that supports a plurality of user devices. In FIG. 2, reference numerals 292A to 292G refer to cells, reference numerals 298A to 298G refer to base stations (BS) or node Bs and reference numerals 296A to 296J refer to access user devices (a.k.a. user equipments (UE)). Cell size may vary. Any of a variety of algorithms and methods may be used to schedule transmissions in system 290. System 290 provides communication for a number of cells 292A through 292G, each of which is serviced by a corresponding base station 298A through 298G, respectively.

In one aspect, the total number of transmitted bits in a codeword is equal to the sum of information bits and redundant bits. The code rate of an error correction code is defined as the ratio of information bits to the total number of transmitted bits. Error correction codes include block codes, convolutional codes, turbo codes, low density parity check (LDPC) codes, and combinations thereof. In one example, LDPC codes may be block codes or convolutional LDPC codes. In one example, turbo codes provide a powerful technique for error correction in wireless communication systems. One skilled in the art would understand that list of codes present herein are examples and not exhaustive. Thus, other codes may be used without affecting the spirit or scope of the present disclosure.

In certain scenarios, the wireless propagation environment may be characterized as a time varying fading channel. In this case, the communications performance may be degraded due to the channel fading. One means of mitigating errors due to channel fading is deliberate distribution of encoded blocks across time as a form of time diversity. Time diversity is a generic transmission technique where error bursts are spread over time to facilitate error correction.

In one example, a turbo coder consists of two parallel, identical encoders, separated by a bit interleaver. A long turbo codeword with time diversity may improve performance in a fading channel. However, the turbo decoder in the receiver must store the turbo decoder input of a whole superframe which may require significant memory resources.

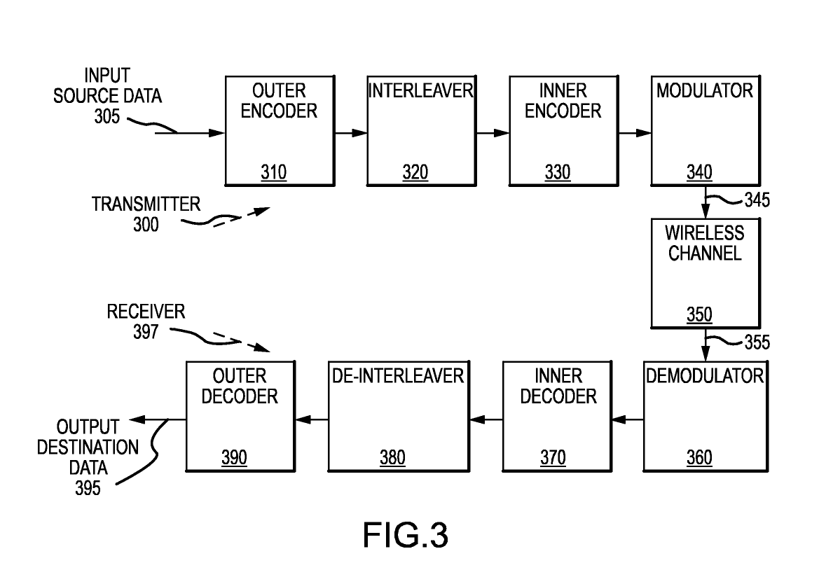

FIG. 3 conceptually illustrates an example of a wireless communication system which employs a concatenated code. In one aspect, the wireless communication system comprises a transmitter 300, a wireless channel 350, and a receiver 397 coupled to an output destination data 395. The transmitter 300 receives an input source data 305. A concatenated code consists of two codes: an outer code and an inner code. In one aspect, the transmitter 300 comprises an outer encoder 310, an interleaver 320, an inner encoder 330, and a modulator 340 for processing the input source data 305 to produce a transmitted signal 345. The wireless channel 350 propagates the transmitted signal 345 from the transmitter 300 and delivers a received signal 355. The received signal 355 is an attenuated, distorted version of transmitted signal 345 along with additive noise. The receiver 397 receives the received signal 355. In one aspect, the receiver 397 comprises a demodulator 360, an inner decoder 370, a deinterleaver 380, and an outer decoder 390 for processing the received signal 355 to produce the output destination data 395. Not shown in FIG. 3 are a high power amplifier and a transmit antenna associated with the transmitter 300. Also not shown are a receive antenna and a low noise amplifier associated with the receiver 397.

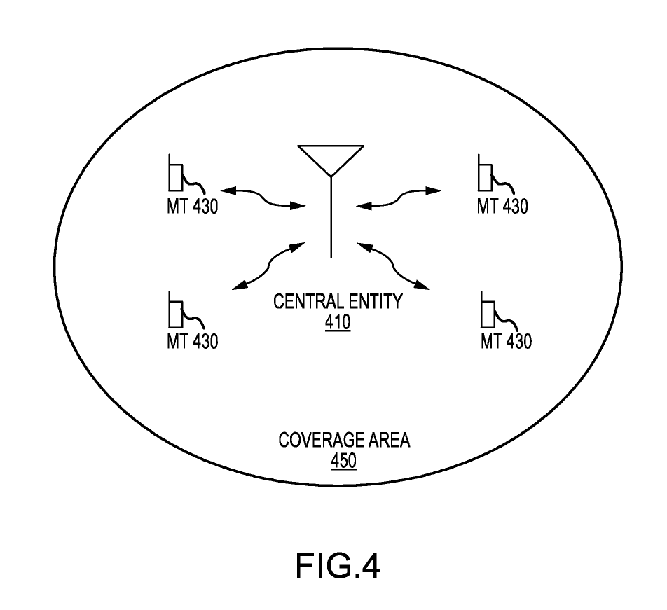

In one example, the transmitter 300 and receiver 397 conform to the FLO Technology specification approved by the FLO FORUM. FLO Technology is a wireless broadcast standard used for broadcasting information, such as multimedia content, from a central entity, e.g. a base station, to a plurality of mobile terminals. FIG. 4 conceptually illustrates an example FLO system with central entity 410 and a plurality of mobile terminals 430. The central entity 410 transmits the transmitted signal to the plurality of mobile terminals 430 within its coverage area 450. In one aspect, information is transmitted in the forward direction only, i.e. from the central entity 410 to the mobile terminals 430.

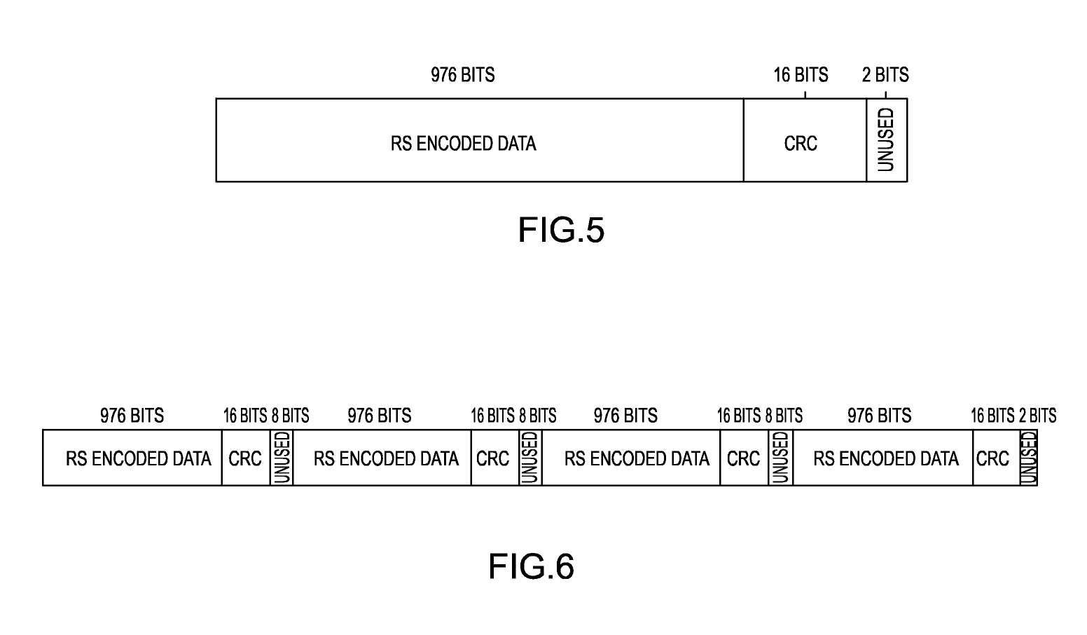

FIG. 5 conceptually illustrates an example of a FLO turbo packet structure. In one aspect, the data bits are Reed-Solomon encoded and formatted as Reed-Solomon (RS) code blocks. Each RS code block consists of 16 Medium Access Control (MAC) packets. Each MAC packet contains 994 bits with a structure as shown in FIG. 5. For example, each MAC packet contains 976 RS-encoded bits, 16 cyclic redundancy check (CRC) bits, and 2 unused bits. Each MAC packet is turbo encoded where the 16 turbo packets of each code block are equally distributed in all frames of the superframe. That is, one frame contains 4 turbo encoded packet. The turbo encoded bits of each MAC packet are then mapped into modulation symbols which are in turn modulated onto OFDM subcarriers. For example, the modulation symbols may be quaternary phase shift keying (QPSK), 16-level quadrature amplitude modulation (16QAM), or layered QPSK modulation symbols. In one example, the modulation symbols are modulated onto subcarriers of one, or a few adjacent, OFDM symbols in the same frame. The encoded bits in a turbo packet are transmitted at the same time if they are scheduled on one OFDM symbol, or if they are scheduled on different OFDM symbols adjacent in time. As a result, turbo decoding in current FLO systems utilizes very limited time diversity especially at low platform speed. In one aspect, time diversity is mainly achieved in a Reed-Solomon decoding process.

In one aspect, an increase in turbo code block size results in a performance gain of a few tenths of a dB in an additive white Gaussian noise (AWGN) channel. However, in another aspect, if the turbo encoded blocks are distributed across multiple frames, better time diversity and improved system performance under time varying fading channels may be attained. For example, at a packet error criterion of 10⁻², the symbol energy/noise density Eₛ/N₀ threshold is lowered by approximately 1.7 dB by distributing a 4K turbo encoded packet over 4 frames instead of using the same frame due to the improved time diversity.

FIG. 6 conceptually illustrates an example of a 4K code block length turbo packet structure. In another aspect, to make a turbo coding change transparent to the medium access control (MAC) layer, for 1K (actually 994) length FLO MAC packets are combined to form a data packet shown in FIG. 6. In one example, a 4K (actually 3994) long data packet is turbo encoded into one single long coded packet.

In another example, the 8K and 16K code block length turbo packets are generated similarly. In another example, to achieve more time diversity, a superframe may be separated into eight or sixteen frames.

In one aspect, since time diversity may be effectively achieved by dividing a turbo encoded packet into sub-packets and then scheduling each sub-packet in a different frame, the Reed Solomon code used in current FLO systems may not be needed. Therefore, it would be desirable that the adjacent turbo encoder output bits are scheduled to different frames of a superframe to achieve more time diversity gain.

For example, the output bits of a current FLO turbo encoder are ordered as: X₀, Y_{0,0}, Y′_{0,1}, X₁, Y_{1,0}, Y′_{1,1}, X₂, Y_{2,0}, Y′_{2,1}, X₃, Y_{3,0}, Y′_{3,1}, . . . for the rate ⅓ case, where Xᵢ is the systematic bit, Y_{i,0} is its first parity bit of the first constituent code, and Y′_{i,1} is the second parity bit of the second constituent code. Y′_{i,1} is an interleaved parity which does not align with Xᵢ. But, Y_{i,0} aligns with Xᵢ as a pair.

In one aspect, a round-robin block interleaving scheme may be used to separate adjacent bits into different frames in a deterministic manner. Table 1 illustrates an example of block interleaving at a rate ⅓ for allocating the turbo encoded bits within 4 frames. For example, Table 1 illustrates a rate ⅓ case where the block interleaver allocates the systematic bit and first parity bit of the first constituent code in different frames of a superframe when there are 4 frames per superframe.

TABLE 1

| Frame 1 | Frame 2 | Frame 3 | Frame 4 |
|---|---|---|---|
| X₀ | Y_{0, 0} | Y′_{0, 1} | X₁ |
| Y_{1, 0} | Y′_{1, 1} | X₂ | Y_{2, 0} |
| Y′_{2, 1} | X₃ | Y_{3, 0} | Y′_{3, 1} |

The turbo encoder output bit sequences of rate ½ and rate ⅔ codes are very similar. Table 2 illustrates an example of block interleaving at a rate ½ for allocating turbo encoded bits within 4 frames. Table 3 illustrates an example of block interleaving at a rate ⅔ for allocating turbo encoded bits within 4 frames. For example, Table 2 and Table 3 show how the block interleaving scheme works for rate ½ and rate ⅔ turbo encoded bits with 4 frames per superframe. For rate ½ case with 4 (or 16) frames per superframe, there is an option of performing one cyclic bit shift for every odd 4 (or 16) bit group in order to avoid the case that all systematic bits are scheduled to particular frames.

TABLE 2

| Bit | | | | |
|---|---|---|---|---|
| group | Frame 1 | Frame 2 | Frame 3 | Frame 4 |
| 0 | X₀ | Y_{0, 0} | X₁ | Y′_{1, 1} |
| 1 | Y′_{3, 1} | X₂ | Y_{2, 0} | X₃ |
| 2 | X₄ | Y_{4, 0} | X₅ | Y′_{5, 1} |
| 3 | Y′_{7, 1} | X₆ | Y_{6, 0} | X₇ |

TABLE 3

| Frame 1 | Frame 2 | Frame 3 | Frame 4 |
|---|---|---|---|
| X₀ | Y_{0, 0} | X₁ | X₂ |
| X₃ | Y′_{3, 1} | X₄ | Y_{4, 0} |
| X₅ | X₆ | X₇ | Y′_{7, 1} |

In another aspect, systematic bits may be scheduled in the first few frames followed by parity bits to obtain power savings under good channel conditions. For example, with a rate ½ code, systematic bits are scheduled in the frames of the first half superframe, while parity bits are scheduled in the frames of the second half superframe. Hence, in a high signal/noise ratio (SNR) channel, the receiver can decode the packets successfully as a rate ⅔ code with the parity bits only from the 3^{rd} quarter of the superframe. As a result, the receiver does not need to wake up during the 4^{th} quarter of the superframe to save handset power. In one example, simulation results show that for rate ⅓ and rate ½ turbo codes at medium and high Doppler speed there is no noticeable performance degradation due to the scheduling of all systematic bits at the front frames.

In another aspect, performance can be enhanced by boosting the log likelihood ratio (LLR) of CRC-passed segments of the turbo code block to reduce the number of decoding iteration. Since there are multiple MAC packets in the long turbo code block, and each MAC packet has its own CRC, one can use such side information in turbo decoding. When one or more CRC passing during a specific turbo decoding iteration, the corresponding LLRs will be boosted to the maximum value. In one example, the number of decoding iterations is reduced.

Disclosed herein is a scheme to reduce the memory requirement for storing the turbo decoder input of a superframe to support the scheme of long turbo coding with time diversity. Since a long turbo codeword with time diversity can enhance FLO performance by at least 2 dB in fading channel, the bit level log likelihood ratio (LLR), which is the input of a turbo decoder for an entire superframe, should be stored before the start of turbo decoding. The log likelihood ratio (LLR) is the logarithm of the ratio of the probability for two distinct hypotheses in a statistical decision test. In one example, if a mobile device (e.g., handset) supports a peak data rate at 1.0 Mbit per second, for turbo code rates of ⅓, 1/2 and ⅔, then the memory size needed to store bit LLR for one superframe with bit widths of 4, 5 and 6 is listed in Table 4. Table 4 lists the memory size needed to store 1 superframe of LLR for 1 Mbit/sec peak rate.

TABLE 4

| Code rate | 6-bit LLR | 5-bit LLR | 4-bit LLR |
|---|---|---|---|
| 1/3 | 18 Mbit | 15 Mbit | 12 Mbit |
| 1/2 | 12 Mbit | 10 Mbit | 8 Mbit |
| 2/3 | 9 Mbit | 7.5 Mbit | 6 Mbit |

As can be seen from Table 4, a rate ⅓ turbo code requires the most memory size since it has the most parity bits among all three code rate cases. If the bit width of code rate ⅓ is 4, a 12-Mbit memory size is sufficient to store the 6-bit LLR in both code rate ½ and ⅔ cases. Since the rate ⅓ code is the most powerful code (i.e., the lowest error rate) of all three cases, the degradation due to the bit width reduction from 6 to 4 is likely acceptable.

In one example, a memory bank has a 24-bit width. The turbo decoder input can be stored in the memory bank in a manner such that each memory read can access the bit LLR of two systematic bits along with the bit LLR of their parity bits.

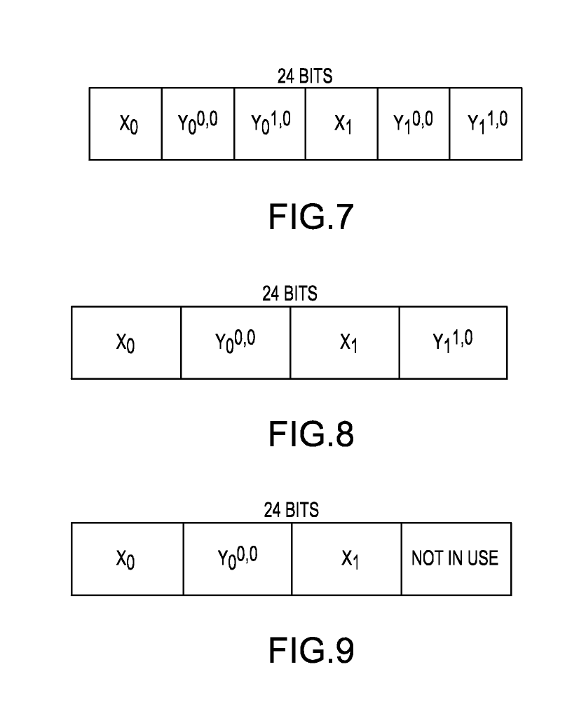

FIG. 7 conceptually illustrates an example of an input symbol storage arrangement for a code rate of ⅓ and a bit width of 4 bits. FIG. 8 conceptually illustrates an example of an input symbol storage arrangement for a code rate of ½ and a bit width of 6 bits. FIG. 9 conceptually illustrates an example of an input symbol storage arrangement for a code rate of ⅔ and a bit width of 6 bits. In FIGS. 7-9, X refers to the systematic bits (i.e. information bits) LLR and Y refers to the parity bits LLR.

In the case of code rate ⅔, only 9-Mbit memory size is needed as shown in Table 4, and the last 6-bit portion of each 24-bit memory location is skipped. Additionally, the 12-Mbit memory size can also support the rate ⅔ code. Hence, with 24-bit wide memory, one memory read can access the bit LLR of two systematic bits along with the bit LLR of their parity bits. For rate ⅕ code for overhead information symbols (OIS), a small memory bank with bit width of 30 may be allocated separately.

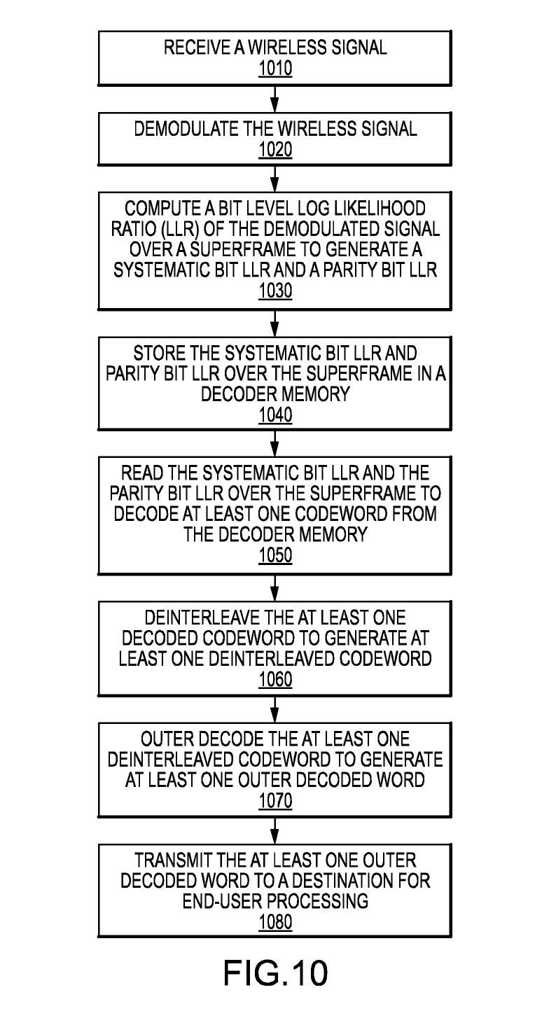

FIG. 10 conceptually illustrates an example flow diagram for efficient memory allocation for turbo decoder input with a long turbo codeword. In block 1010, a wireless signal is received. In one example, the wireless signal is comprised of Reed-Solomon (RS) code blocks and/or turbo packets. In one example, the wireless signal is modulated by QPSK, 16 QAM or layered QPSK. In another example, the wireless signal is modulated by OFDM. In another example, the wireless signal includes at CRC bits.

Following block 1010, in block 1020, the wireless signal is demodulated. In block 1030, a bit level log likelihood ratio (LLR) of the demodulated signal (i.e., demodulated wireless signal) over a superframe to generate at least one systematic bit LLR and at least one parity bit LLR is computed. In one example, the at least one systematic bit LLR and the at least one parity bit LLR are boosted to their maximum values. Following block 1030, in block 1040, the at least one systematic bit LLR and the at least one parity bit LLR over the superframe is stored in a decoder memory. In one example, the at least one systematic bit LLR and the at least one parity bit LLR are stored in the decoder memory such that each memory read can access at least one systematic bit LLR along with an associated parity bit LLR.

In block 1050, the systematic bit LLR and the parity bit LLR over the superframe is read and used to decode at least one codeword from the decoder memory. In one example, the at least one codeword incorporates time diversity. In one example, the at least one codeword includes a CRC bit.

In block 1060, the at least one decoded codeword is deinterleaved to generate at least one deinterleaved codeword. In one example, the at least one deinterleaved codeword incorporates block deinterleaving or round-robin block deinterleaving. In block 1070, the at least one deinterleaved codeword is decoded to generate at least one outer decoded word. In block 1080, the at least one outer decoded word is transmitted to a destination for end-user processing.

One skilled in the art would understand that the steps disclosed in the example flow diagram in FIG. 10 may be interchanged in their order without departing from the scope and spirit of the present disclosure. Also, one skilled in the art would understand that the steps illustrated in the flow diagram are not exclusive and other steps may be included or one or more of the steps in the example flow diagram may be deleted without affecting the scope and spirit of the present disclosure.

Those of skill would further appreciate that the various illustrative components, logical blocks, modules, circuits, and/or algorithm steps described in connection with the examples disclosed herein may be implemented as electronic hardware, firmware, computer software, or combinations thereof. To clearly illustrate this interchangeability of hardware, firmware and software, various illustrative components, blocks, modules, circuits, and/or algorithm steps have been described above generally in terms of their functionality. Whether such functionality is implemented as hardware, firmware or software depends upon the particular application and design constraints imposed on the overall system. Skilled artisans may implement the described functionality in varying ways for each particular application, but such implementation decisions should not be interpreted as causing a departure from the scope or spirit of the present disclosure.

For example, for a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, other electronic units designed to perform the functions described therein, or a combination thereof. With software, the implementation may be through modules (e.g., procedures, functions, etc.) that perform the functions described therein. The software codes may be stored in memory units and executed by a processor unit. Additionally, the various illustrative flow diagrams, logical blocks, modules and/or algorithm steps described herein may also be coded as computer-readable instructions carried on any non-transitory computer-readable medium known in the art or implemented in any computer program product known in the art.

In one or more examples, the steps or functions described herein may be implemented in hardware, software, firmware, or any combination thereof. If implemented in software, the functions may be stored as one or more instructions or code on a non-transitory computer-readable medium. By way of example, and not limitation, such non-transitory computer-readable media can comprise any combination of RAM, ROM, EEPROM, CD-ROM or other optical disk storage, magnetic disk storage or other magnetic storage devices, or any other non-transitory medium that can be used to carry or store desired program code in the form of instructions or data structures and that can be accessed by a computer.

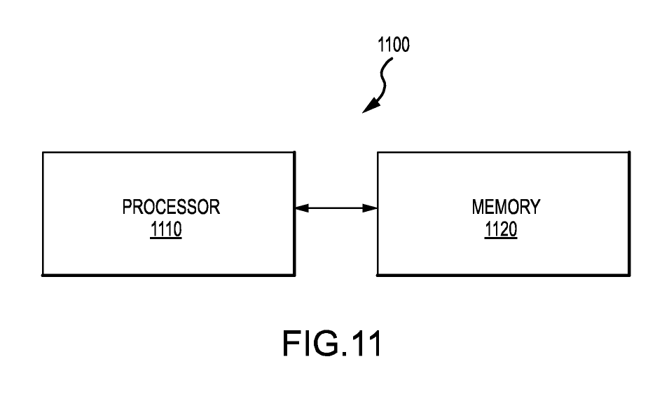

In one example, the illustrative components, flow diagrams, logical blocks, modules and/or algorithm steps described herein are implemented or performed with one or more processors. In one aspect, a processor is coupled with a memory which stores data, metadata, program instructions, etc. to be executed by the processor for implementing or performing the various flow diagrams, logical blocks and/or modules described herein. FIG. 11 conceptually illustrates an example of a device 1100 comprising a processor 1110 in communication with a memory 1120 for executing the processes for efficient memory allocation for turbo decoder input with a long turbo codeword. In one example, the device 1100 is used to implement the algorithm illustrated in FIG. 10. In one aspect, the memory 1120 is located within the processor 1110. In another aspect, the memory 1120 is external to the processor 1110. In one aspect, the processor includes circuitry for implementing or performing the various flow diagrams, logical blocks and/or modules described herein.

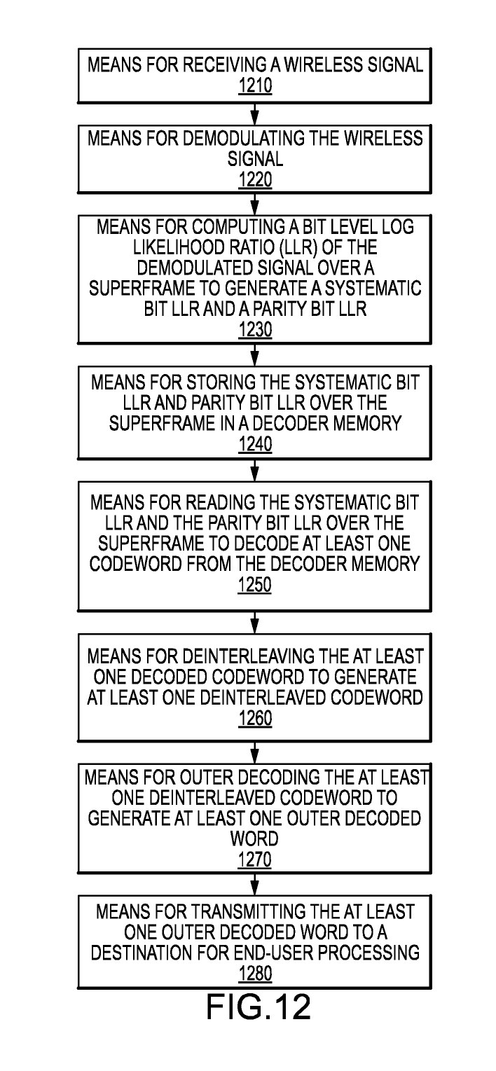

FIG. 12 conceptually illustrates an example of a device 1200 suitable for efficient memory allocation for turbo decoder input with a long turbo codeword. In one aspect, the device 1200 is implemented by at least one processor comprising one or more modules configured to provide different aspects of improving call set-up performance during transition between wireless systems as described herein in blocks 1210, 1220, 1230, 1240, 1250, 1260, 1270 and 1280. For example, each module comprises hardware, firmware, software, or any combination thereof. In one aspect, the device 500 is also implemented by at least one memory in communication with the at least one processor.

The previous description of the disclosed aspects is provided to enable any person skilled in the art to make or use the present disclosure. Various modifications to these aspects will be readily apparent to those skilled in the art, and the generic principles defined herein may be applied to other aspects without departing from the spirit or scope of the disclosure.

1. A method for memory allocation for turbo decoder input with a long turbo codeword, the method comprising:
computing a bit level log likelihood ratio (LLR) of a demodulated signal over a superframe to generate at least one systematic bit LLR and at least one parity bit LLR;
storing the at least one systematic bit LLR and the at least one parity bit LLR over the superframe in a decoder memory; and
reading the systematic bit LLR and the parity bit LLR over the superframe to decode at least one codeword from the decoder memory.

2. The method of claim 1 wherein the at least one systematic bit LLR and the at least one parity bit LLR are stored in the decoder memory such that each memory read can access at least one systematic bit LLR along with an associated parity bit LLR.

3. The method of claim 2 further comprising deinterleaving the at least one decoded codeword to generate at least one deinterleaved codeword.

4. The method of claim 3 wherein the at least one deinterleaved codeword incorporates either block deinterleaving or round-robin block deinterleaving.

5. The method of claim 3 further comprising outer decoding the at least one deinterleaved codeword to generate at least one outer decoded word.

6. The method of claim 5 further comprising transmitting the at least one outer decoded word to a destination for end-user processing.

7. The method of claim 1 wherein the at least one codeword incorporates time diversity.

8. The method of claim 1 further comprising:
receiving a wireless signal modulated by one or more of the following: QPSK, layered QPSK, 16 QAM or OFDM; and
demodulating the wireless signal.

9. The method of claim 8 wherein the wireless signal comprises of either Reed-Solomon (RS) code blocks or turbo packets.

10. The method of claim 1 wherein the at least one systematic bit LLR and the at least one parity bit LLR are boosted to their maximum values and the at least one codeword includes a CRC bit.

11. An apparatus for memory allocation for turbo decoder input with a long turbo codeword, the apparatus comprising a processor and a memory, the memory containing program code executable by the processor for performing the following:
computing a bit level log likelihood ratio (LLR) of a demodulated signal over a superframe to generate at least one systematic bit LLR and at least one parity bit LLR;
storing the at least one systematic bit LLR and the at least one parity bit LLR over the superframe in a decoder memory; and
reading the systematic bit LLR and the parity bit LLR over the superframe to decode at least one codeword from the decoder memory.

12. The apparatus of claim 11 wherein the at least one systematic bit LLR and the at least one parity bit LLR are stored in the decoder memory such that each memory read can access at least one systematic bit LLR along with an associated parity bit LLR.

13. The apparatus of claim 12 wherein the memory further comprising program code for deinterleaving the at least one decoded codeword to generate at least one deinterleaved codeword.

14. The apparatus of claim 13 wherein the at least one deinterleaved codeword incorporates either block deinterleaving or round-robin block deinterleaving.

15. The apparatus of claim 13 wherein the memory further comprising program code for outer decoding the at least one deinterleaved codeword to generate at least one outer decoded word.

16. The apparatus of claim 15 wherein the memory further comprising program code for transmitting the at least one outer decoded word to a destination for end-user processing.

17. The apparatus of claim 11 wherein the at least one codeword incorporates time diversity.

18. The apparatus of claim 11 wherein the memory further comprising program code for:
receiving a wireless signal modulated by one or more of the following: QPSK, layered QPSK, 16 QAM or OFDM; and
demodulating the wireless signal.

19. The apparatus of claim 18 wherein the wireless signal comprises of either Reed-Solomon (RS) code blocks or turbo packets.

20. The apparatus of claim 11 wherein the at least one systematic bit LLR and the at least one parity bit LLR are boosted to their maximum values and the at least one codeword includes a CRC bit.

21. An apparatus for memory allocation for turbo decoder input with a long turbo codeword, the apparatus comprising:
means for computing a bit level log likelihood ratio (LLR) of a demodulated signal over a superframe to generate at least one systematic bit LLR and at least one parity bit LLR;
means for storing the at least one systematic bit LLR and the at least one parity bit LLR over the superframe in a decoder memory; and
means for reading the systematic bit LLR and the parity bit LLR over the superframe to decode at least one codeword from the decoder memory.

22. The apparatus of claim 21 wherein the at least one systematic bit LLR and the at least one parity bit LLR are stored in the decoder memory such that each memory read can access at least one systematic bit LLR along with an associated parity bit LLR.

23. The apparatus of claim 22 further comprising means for deinterleaving the at least one decoded codeword to generate at least one deinterleaved codeword.

24. The apparatus of claim 23 wherein the at least one deinterleaved codeword incorporates either block deinterleaving or round-robin block deinterleaving.

25. The apparatus of claim 23 further comprising means for outer decoding the at least one deinterleaved codeword to generate at least one outer decoded word.

26. The apparatus of claim 25 further comprising means for transmitting the at least one outer decoded word to a destination for end-user processing.

27. The apparatus of claim 21 wherein the at least one codeword incorporates time diversity.

28. The apparatus of claim 21 further comprising:
means for receiving a wireless signal modulated by one or more of the following: QPSK, layered QPSK, 16 QAM or OFDM; and
means for demodulating the wireless signal.

29. The apparatus of claim 28 wherein the wireless signal comprises of either Reed-Solomon (RS) code blocks or turbo packets.

30. The apparatus of claim 21 wherein the at least one systematic bit LLR and the at least one parity bit LLR are boosted to their maximum values and the at least one codeword includes a CRC bit.

31. A computer-readable medium storing a computer program, wherein execution of the computer program is for:
computing a bit level log likelihood ratio (LLR) of a demodulated signal over a superframe to generate at least one systematic bit LLR and at least one parity bit LLR;
storing the at least one systematic bit LLR and the at least one parity bit LLR over the superframe in a decoder memory; and
reading the systematic bit LLR and the parity bit LLR over the superframe to decode at least one codeword from the decoder memory.

32. The computer-readable medium of claim 31 wherein the at least one systematic bit LLR and the at least one parity bit LLR are stored in the decoder memory such that each memory read can access at least one systematic bit LLR along with an associated parity bit LLR.

33. The computer-readable medium of claim 32 wherein execution of the computer program is also for deinterleaving the at least one decoded codeword to generate at least one deinterleaved codeword.

34. The computer-readable medium of claim 33 wherein the at least one deinterleaved codeword incorporates either block deinterleaving or round-robin block deinterleaving.

35. The computer-readable medium of claim 33 wherein execution of the computer program is also for outer decoding the at least one deinterleaved codeword to generate at least one outer decoded word.

36. The computer-readable medium of claim 35 wherein execution of the computer program is also for transmitting the at least one outer decoded word to a destination for end-user processing.

37. The computer-readable medium of claim 31 wherein the at least one codeword incorporates time diversity.

38. The computer-readable medium of claim 31 wherein execution of the computer program is also for:
receiving a wireless signal modulated by one or more of the following: QPSK, layered QPSK, 16 QAM or OFDM; and
demodulating the wireless signal.

39. The computer-readable medium of claim 38 wherein the wireless signal comprises of either Reed-Solomon (RS) code blocks or turbo packets.

40. The computer-readable medium of claim 31 wherein the at least one systematic bit LLR and the at least one parity bit LLR are boosted to their maximum values and the at least one codeword includes a CRC bit.
